(19) United States
(12) Patent Application Publication
(10) Pub. No.: US 2013/0276696 A1
(43) Pub. Date: Oct. 24, 2013

(54) PRODUCTION METHOD FOR FLAT SUBSTRATE WITH LOW DEFECT DENSITY

(71) Applicant: Nanocrystal Asia Inc., Taipei (TW)

(72) Inventors: Chong-Ming LEE, Taipei (TW); Andrew Eng-Jia Lee, Taipei (TW)

(21) Appl. No.: 13/867,877

(22) Filed: Apr. 22, 2013

Related U.S. Application Data
(60) Provisional application No. 61/637,065, filed on Apr. 23, 2012.

(51) Int. Cl. C30B 25/04

(52) U.S. Cl. CPC C30B 25/04
USPC 117/95

(57) ABSTRACT

The present invention discloses a production method for a flat substrate with low defect density. The method includes steps of: providing a substrate, performing selective growth of nanowires, performing lateral epitaxial growth of the nanowires, performing lateral coalescence of widened nanowires, performing high temperature annealing, and performing LED structure growth. The production method of the present invention generates vertical and lateral growth of the nanowires by choosing different concentrations of additives to produce a flat film, and generate a high efficiency LED semiconductor structure after annealing the flat film.

### BACKGROUND OF THE INVENTION

1. Technical Field

The present invention relates to a production method for a flat substrate with low defect density. More particularly, the present invention relates to a production method with vertical and lateral growth of nanowires for a flat substrate with low defect density.

2. Description of Related Art

According to the prior art, additives of different concentrations are added thereby to cause gallium nitride (GaN) nanowires to undergo epitaxy lateral overgrowth for producing a gallium nitride film (GaN Film). The additives enable each nanowire to widen independently, vertically, and gradually in an upward direction. A single additive of specific concentration has a disadvantage, that is, the nanowires widen laterally to a certain extent but stop widening thereafter.

Referring to FIG. 1, there is shown a schematic view of a conventional gallium nitride film. Additives not only, enable the nanowires to widen, but also enable the nanowires to grow vertically at a vertical growth rate of 2 μm/hr or higher. Hence, the vertical growth of the nanowires is very sensitive to the additive concentration. The additive concentration is therefore to cause the nanowires to differ in height, and bumps 200 are formed on multiple regions of the surface of a gallium nitride film 100 above the nanowires. The bumps 200 are 2.5˜4.5 μm high, and the scope of the bumps 200 in each region is of dimensions 5 μm×12 μm.

Referring to FIG. 2, there is shown a schematic view of a conventional LED epitaxy structure, wherein u-GaN is un-doped gallium nitride (GaN), n-GaN is GaN doped with negative ions, p-GaN is GaN doped with positive ions, and MQW is multiple quantum well.

As shown in FIG. 1 and FIG. 2, the bumps 200 on the surface of the gallium nitride film 100 (GaN film) are likely to cause each layer of films to form an uneven surface during a backend LED manufacturing process. Furthermore, the accumulation of lattice dislocation renders the film structure fragile and brittle thereby to reduce internal quantum efficiency, reduce the probability of electron-hole recombination, and reduce light output efficiency. Accordingly, it is imperative to provide a production method that reduces the formation of the bumps 200 on the surface of the gallium nitride film 100.

### BRIEF SUMMARY OF THE INVENTION

The present invention discloses a production method for a flat substrate with low defect density. The method includes steps of: providing a substrate, performing selective growth of nanowires, performing lateral epitaxial growth of the nanowires, performing lateral coalescence of widened nanowires, performing high temperature annealing and performing LED structure growth. The production method of the present invention generates vertical and horizontal growth of the nanowires by choosing different concentrations of additives to produce a flat film, and generate a high efficiency LED semiconductor structure after annealing the flat film.

To achieve these and other effects, the present invention provides a production method for flat substrate with low defect density, comprising following steps of: providing a substrate, wherein the substrate is a base for growing subsequent layers, an un-doped semiconductor layer is formed on the substrate and an insulation layer is formed on the un-doped semiconductor layer, and the insulation layer has plural holes and is formed by coating an insulation material on the un-doped semiconductor layer, undergoing exposure and development the insulation material, and dry etching, so that the insulation layer functions as a selective growth mask with the holes; performing selective growth, wherein nanowires vertically grow on the un-doped semiconductor layer through the holes of the selective growth mask; performing lateral epitaxial growth, wherein the nanowires are grown laterally to form widened nanowires, the lateral epitaxial growth of the widened nanowires is controlled by adding additives of different concentration gradients; performing lateral coalescence, wherein a flat bump-free coalescence film from the top of the widened nanowires is formed; performing high temperature annealing, wherein a grain boundary at the junction of the widened nanowires is eliminated with a high temperature gas; and performing LED structural growth, wherein a monocrystalline semiconductor structure grows from the flat bump-free coalescence film, and the monocrystalline semiconductor structure is used to manufacture light-emitting components.

By implementing the present invention, at least the following progressive effects can be achieved:

1. The bumps on gallium nitride films to make a flat substrate are reduced, so as to result in promoting the quantum efficiency in the LED epitaxy structure to enhance the light output efficiency of LED.

2. The gaps between the adjacent nanowires give rise to different reflective indexes along the outgoing light path thereby to greatly reduce total reflection of incident light, increase the scattering angle of the incident light, and thus enhance the light output efficiency of the light emissions.

The features and advantages of the present invention are detailed hereinafter with reference to the preferred embodiments. The detailed description is intended to enable a person skilled in the art to gain insight into the technical contents disclosed herein and implement the present invention accordingly. In particular, a person skilled in the art can easily understand the objects and advantages of the present invention by referring to the disclosure of the specification, the claims, and the accompanying drawings.

### BRIEF DESCRIPTION OF THE SEVERAL VIEWS OF THE DRAWINGS

FIG. 1 shows a schematic view of a conventional gallium nitride film;

FIG. 2 shows a schematic view of a conventional LED epitaxy structure;

FIG. 3 is a flow chart of a method of producing a flat substrate with low defect density according to an embodiment of the present invention;

FIG. 4A is a cross-sectional view of a substrate according to an embodiment of the present invention;

FIG. 4B is a top view of a substrate according to an embodiment of the present invention;

FIG. 5A is a cross-sectional view of a step of performing selective growth according to an embodiment of the present invention;

FIG. 5B is a top view of the result of a step of performing selective growth according to an embodiment of the present invention;

FIG. 6A is a top view of a 4-fold nanowire array according to an embodiment of the present invention;

FIG. 6B is a top view of a 6-fold nanowire array according to an embodiment of the present invention;

FIG. 6C is a macroscopic top view of a 6-fold nanowire array according to an embodiment of the present invention;

FIG. 6D is a top view of a 12-fold nanowire array according to an embodiment of the present invention;

FIG. 7A is a cross-sectional view of a step of performing lateral epitaxial growth according to an embodiment of the present invention;

FIG. 7B is a top view of the result of a step of performing lateral epitaxial growth according to an embodiment of the present invention;

FIG. 8A is a cross-sectional view of a step of performing lateral coalescence according to an embodiment of the present invention;

FIG. 8B is a top view of the result of a step of performing lateral coalescence according to an embodiment of the present invention;

FIG. 9A is a cross-sectional view of a step of performing high temperature annealing according to an embodiment of the present invention;

FIG. 9B is a top view of the result of a step of performing high temperature annealing according to an embodiment of the present invention;

FIG. 10A is a cross-sectional view of a step of performing LED structural growth according to an embodiment of the present invention; and

FIG. 10B is a top view of the result of a step of performing LED structural growth according to an embodiment of the present invention.

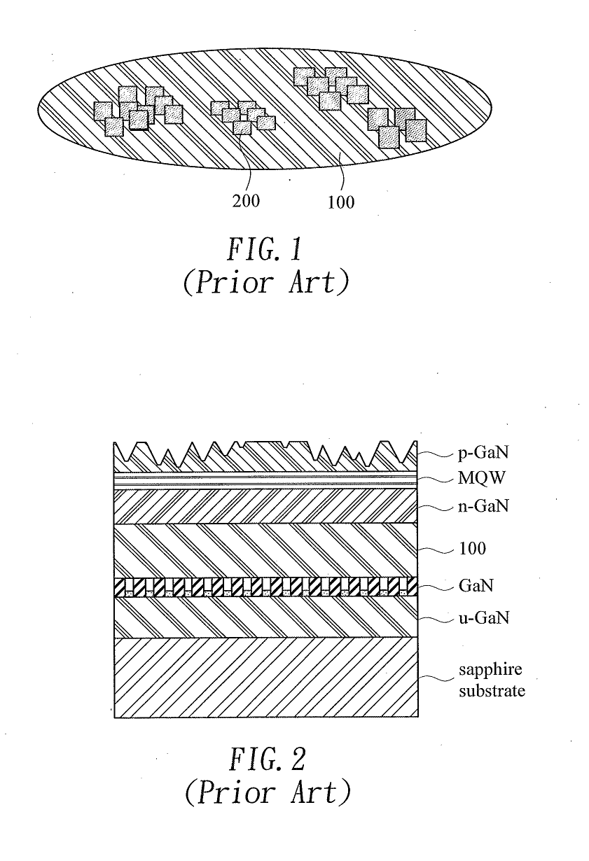

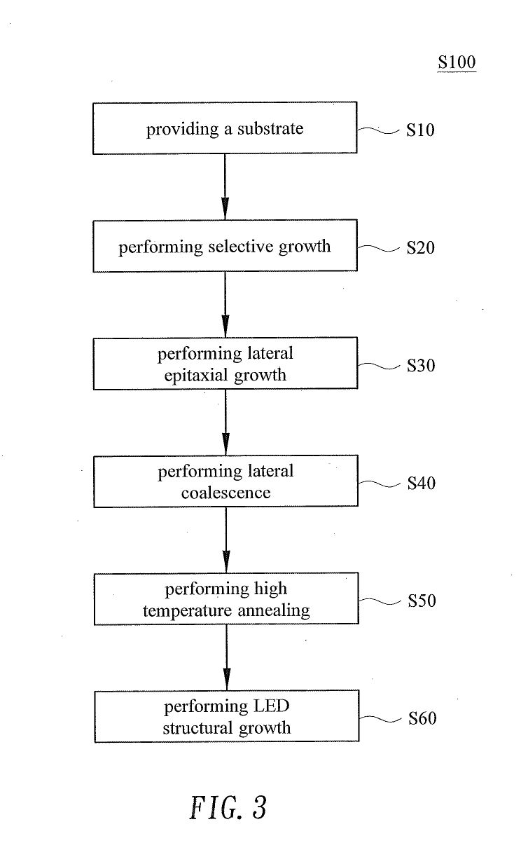

### DETAILED DESCRIPTION OF THE INVENTION

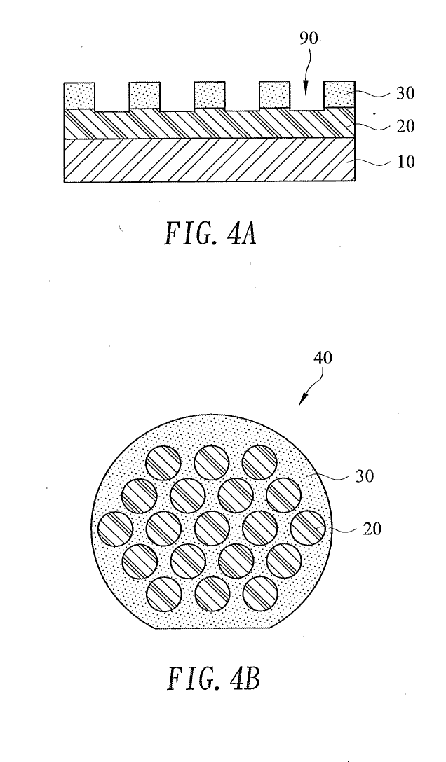

Referring to FIG. 3, a production method (S100) for a flat substrate with low defect density according to an embodiment of the present invention includes steps of: providing a substrate (step S10); performing selective growth (step S20); performing lateral epitaxial growth (step S30); performing lateral coalescence (step S40); performing high temperature annealing (step S50); and performing LED structural growth (step S60).

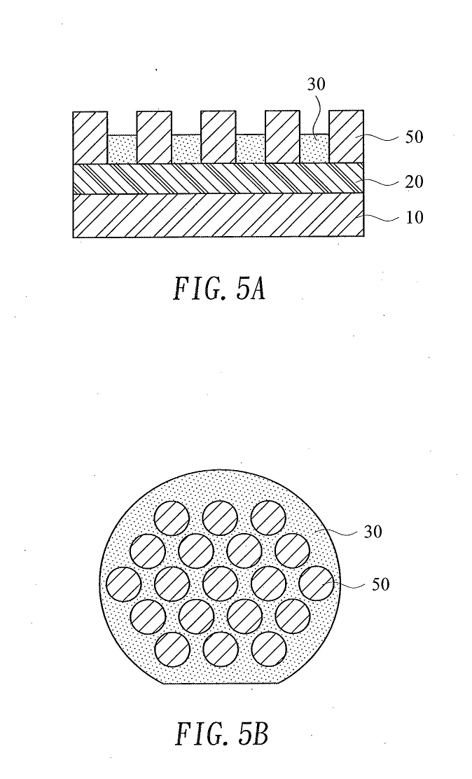

Referring to FIG. 4A and FIG. 4B, in the step of providing a substrate (step S10), a substrate 10 is for use as a base for subsequent LED film growth. Afterward, an un-doped semiconductor layer 20 is grown on the substrate 10, and then an insulation layer 30 is grown on the un-doped semiconductor layer 20. The substrate 10 can be made of silicon (Si), silicon carbide (SiC), sapphire, lithium aluminate, or any material readily conceivable by persons skilled in the art, wherein the silicon substrate can be silicon wafer (111) or silicon wafer (110). In this embodiment, the substrate 10 is made of sapphire.

The un-doped semiconductor layer 20 (such as u-GaN layer) is grown on the sapphire substrate 10 by metal-organic chemical vapor deposition (MOCVD). The un-doped semiconductor layer 20 is made of a semiconductor material, wherein the semiconductor material can be a group III-V compound semiconductor or a group II-VI compound semiconductor, such as gallium nitride (GaN), aluminum nitride (AlN), indium nitride (InN), indium gallium nitride (InGaN), aluminum gallium nitride (AlGaN), or aluminum indium gallium nitride (AlInGaN). In this embodiment, the un-doped semiconductor layer 20 is made of gallium nitride (GaN).

The parameters used in MOCVD can be defined as follows: (1) pressure (P) is between 500 and 1,600 torr, (2) flow rate of NH₃ is 2˜100 slm (standard liter per minute); flow rate of trimethylgallium (TMGa) is 0˜5,000 seem (standard cubic centimeter per minute), (3) annealing temperature is between 500° C. and 1,600° C.

The insulation layer 30 is grown on the un-doped semiconductor layer 20, for example, the insulation layer 30 is formed by a process of Plasma Enhanced Chemical Vapor Deposition (PECVD). PECVD entails applying a radio frequency (RF) voltage to two electrode plates thereby to enable gas between the two electrodes to dissociate and ionized to produce plasma. The auxiliary energy of the plasma helps decrease the temperature of deposition reaction, and thus a gas in the aforesaid plasma state is conducive to chemical reactions, allowing a film of the insulation layer 30 to be deposited on the un-doped semiconductor layer 20 easily.

The thickness of the insulation layer 30 can be 100˜2,000 Å (10 Å=1 nm). In one embodiment, the insulation layer 30 is made of a silica sol-gel material. The silica sol-gel material is gelatinous, with excellent liquidity, and can be easily filled in nanoscale holes. Examples of the silica sol-gel material include silicon dioxide (SiO₂) and silicon nitride (SiNₓ). Thus, the insulation layer 30 can be made of silicon dioxide (SiO₂) or silicon nitride (SiNₓ)

A required pattern of plural holes 90 is transferred onto the insulation layer 30 by nanoscale or microscale imprint lithography, and then undergoes an exposure process, a development process, and a dry etching process to remove a portion of the insulation layer 30, and the desirable pattern of plural holes 90 is kept thereby to form a selective growth mask 40. The insulation layer 30 having the desirable pattern of plural holes 90 can be formed by coating an insulation material on the un-doped semiconductor layer 20, undergoing exposure and development the insulation material, and dry etching, so that the insulation layer 30 functions as the selective growth mask 40 also with the pattern of plural holes. At this point of time, portions of the gallium nitride layer 20 under the holes 90 are not covered with the insulation layer 30 and thus are exposed. The parameters of the holes 90 of the transferred pattern, such as the pitch, dimensions, arrangement, and distribution of the holes 90, can be adjusted as needed for different applications.

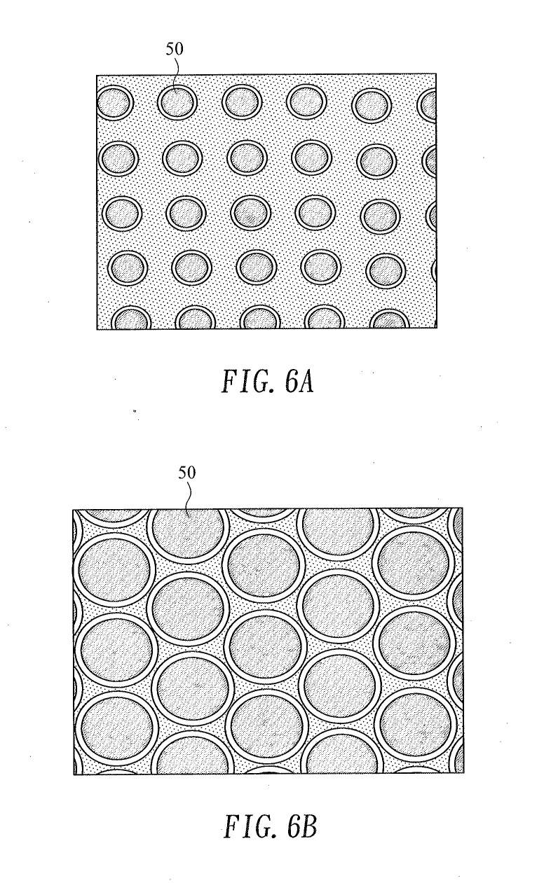

Referring to FIG. 5A and FIG. 5B, in the step of performing selective growth (step S20), nanowires 50 are grown on the gallium nitride layer 20 vertically by metal organic chemical vapor deposition (MOCVD). Since the nanowires 50 cannot grow on the insulation layer 30, the nanowires 50 grow selectively on the un-doped semiconductor layer 20 through the holes 90 of the selective growth mask 40.

The portion of the insulation layer 30 at the periphery of the holes 90 has a specific thickness and thus provides a lateral supporting force for the growth of the nanowires 50, such that the nanowires 50 are separated and spaced apart throughout the process of their upward vertical growth. Defects formed between heterogeneous materials, namely gallium nitride and sapphire, are isolated by the insulation layer 30 and thus do not extend to the nanowires 50 which grow upward and vertically.

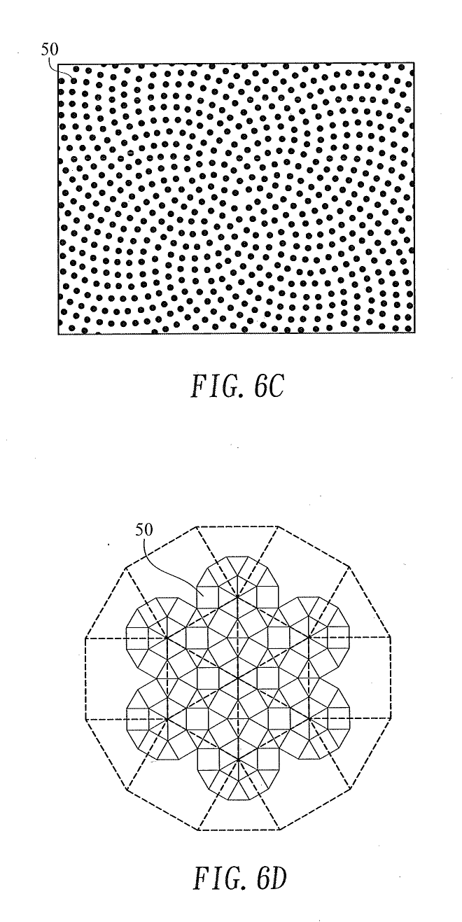

Referring to FIG. 5A and FIG. 6A through FIG. 6D, the nanowires 50 are perpendicular to the gallium nitride layer 20, and can be parallel with respect to each other. The growth shape of the nanowires 50 can be cylindrical or cone shapes, and the shape of cross-section of the nanowires 50 can be rectangle, polygon, square, oval, or circle. In one embodiment, the dimensions of the nanowires 50 are as follows: 20˜6,000 nm in length and 20˜2,000 nm in width. The larger the aspect ratio is, the sharper the nanowires 50 are.

As also shown in FIG. 6A through FIG. 6D, the pitch/spacing of the nanowires 50 can be between 20 nm and 2,000 nm, wherein the pitch/spacing of the nanowires 50 is defined as the distance between the center of two adjacent nanowires 50. The nanowire array formed by the nanowires 50 can be hexagonal or quasi-crystal arrangement (such as 4, 6, 12 fold, wherein fold is defined as a group of nanowires to form a geometry). As for the nanowire symmetry, one direction of the cross-sectional dimension can be much less than 1,000 nm, and in an orthogonal direction, the dimension can be substantially equal to or greater than 1,000 nm. For example: x-axis=1,000 nm; y-axis<<1,000 nm. Which can be arranged as, the length (as known as the height of one nanowire 50) is 1,000 nm, and the width is far less than 1,000 nm. In one embodiment, a best aspect ratio (the length to width ratio) of the nanowires 50 to form a cylinder shape and be mutually parallel is 10 to 3. In other embodiment, the height of one nanowire can be 1 μm and the width of the nanowire can be 300 nm.

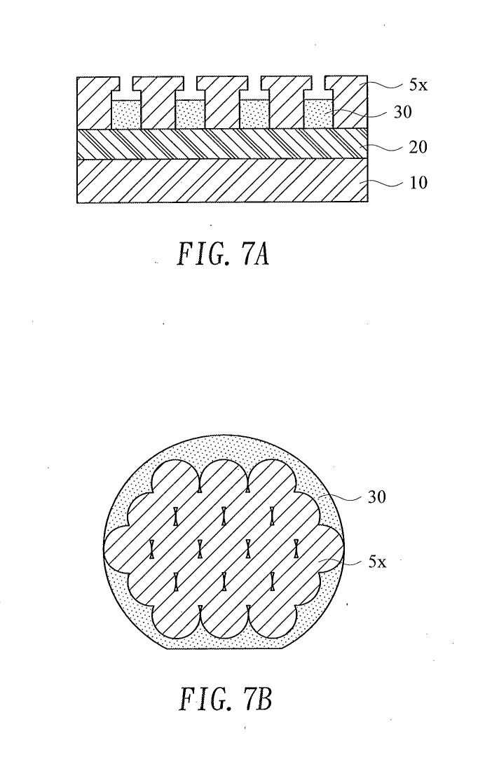

Referring to FIG. 5A, FIG. 7A and FIG. 7B, in the step of performing lateral epitaxial growth (step S30) is to laterally grow the nanowires to form widened nanowires 5x by MOCVD. The width of the widened nanowires 5x is controlled by adding additives of different concentration gradients in the step S30. For example, in a MOCVD reactor, an additive of C1% concentration is added to promote lateral epitaxial growth of the nanowires 50 and thereby to obtain widened nanowires 51. A single additive of specific concentration has a limitation, that is, the nanowires 51 widen laterally to a certain extent but stop widening thereafter. Then the adjustment of C2% concentration enables the lateral widening of the nanowires 51 to continue, and eventually new widened nanowires 52 are obtained.

Hence, the lateral epitaxial growth is characterized in that, given N instances of adjustment of additive concentration, N+1 layers of widened nanowires 5x of different widths are obtained, and the widened nanowires 5x are separated and spaced apart throughout the course of their lateral growth, wherein x denotes an integer equal to or larger than 0, and N denotes an integer equal to or larger than 1. Weight-induced bending or breaking is lessened by means of a thickness resulting from gradual widening. In this embodiment, the additives are TMGa or any other nitrogen-containing elements.

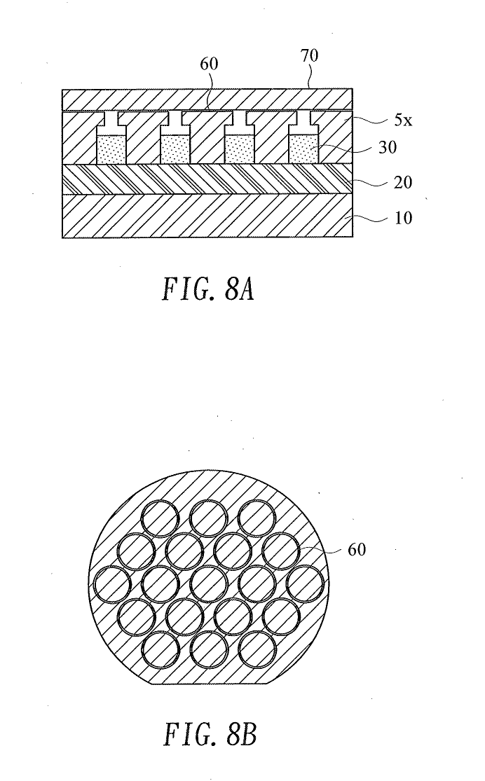

Referring to FIG. 5A, FIG. 8A and FIG. 8B, the step of performing lateral coalescence (step S40) is to form a flat bump-free coalescence film from the top of the widened nanowires 5x. After consecutive N instances of additive concentration adjustment, (N+1) layers of the widened nanowires 5x are obtained, and coalescence starts occurring to the adjacent widened nanowires 5x as soon as they widen laterally to a certain extent and stops as soon as a flat bump-free coalescence film 70 is formed at the top ends of the widened nanowires 5x. The thickness of the coalescence film 70 correlates with the degree of surface flatness and the original geometric characteristics of the nanowires 50. By controlling the height, dimensions, pitch, and arrangement pattern of the mutually independent nanowires 50 and adjusting the application of additives of different concentrations, it is feasible to control the thickness of the coalescence film 70 and optimize the surface flatness of the coalescence film 70.

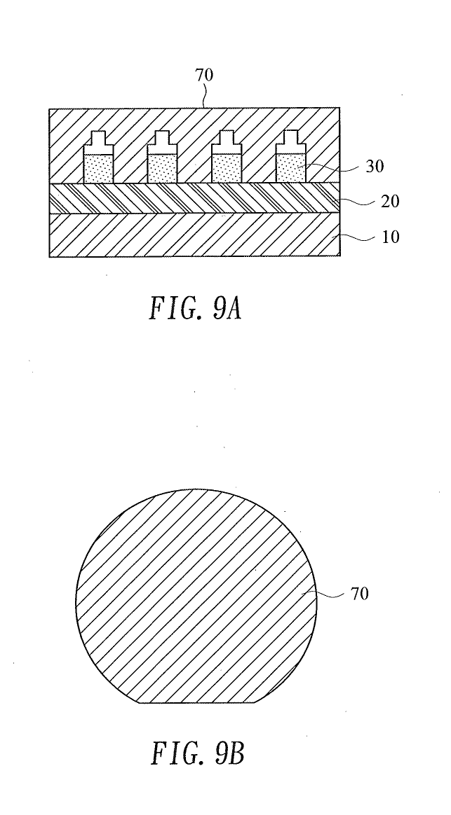

Referring to FIG. 8A to FIG. 9B, as regards the step of performing high temperature annealing (step S50), which is to eliminate a grain boundary at the junction of the widened nanowires. In the course of performing lateral coalescence (step S40) of the widened nanowires 5x, the grain boundary 60 is formed at the junction of two adjacent widened nanowires 5x. The grain boundary 60 has weaker molecular bonding than areas outside the grain boundary 60. Hence, it is necessary to perform annealing with a high temperature gas in order to eliminate the grain boundary 60 and thus provide a defect-free growth matrix. The step of performing high temperature annealing (step S50) not only flattens the coalescence film 70 but also prevents the widened nanowires 5x from severing or collapsing. In this embodiment, the high temperature gas can be high-purity low-unit-price argon gas or hydrogen gas.

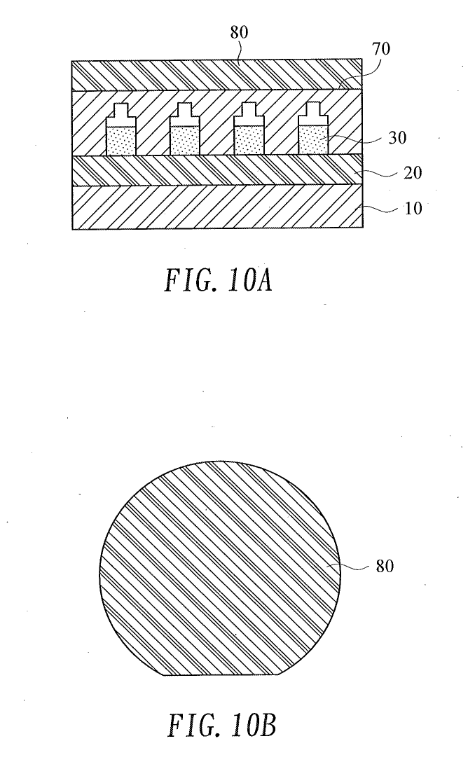

Referring to FIG. 9A, FIG. 10A and FIG. 10B, as regards the step of performing LED structural growth (step S60), the surface of the coalescence film 70 treated by the high temperature annealing step (step S50) is flat and bump-free, and thus it is feasible to grow a monocrystalline semiconductor structure 80 on the coalescence film 70 by Hydride Vapour Phase Epitaxy (HVPE). The widened nanowires 5x treated by the high temperature annealing (step S50) can absorb the thermal stress between heterogeneous materials, namely gallium nitride and sapphire, thereby preventing the monocrystalline semiconductor structure 80 from being damaged or cracked, wherein the monocrystalline semiconductor structure 80 in this embodiment is made of gallium nitride.

The monocrystalline semiconductor structure 80 manufactured by the production method (S100) for a flat substrate with low defect density according to an embodiment of the present invention is used to manufacture light-emitting components. The gaps between the adjacent nanowires 50 give rise to different reflective indexes along the outgoing light path thereby to greatly reduce total reflection of incident light, increase the scattering angle of the incident light, and thus enhance the light output efficiency of the light-emitting components.

The embodiments described above are intended only to demonstrate the technical concept and features of the present invention so as to enable a person skilled in the art to understand and implement the contents disclosed herein. It is understood that the disclosed embodiments are not to limit the scope of the present invention. Therefore, all equivalent changes or modifications based on the concept of the present invention should be encompassed by the appended claims.

What is claimed is:

1. A production method for flat substrate with low defect density, comprising following steps of:
providing a substrate, wherein the substrate is a base for growing subsequent layers, an un-doped semiconductor layer is formed on the substrate and an insulation layer is formed on the un-doped semiconductor layer, and the insulation layer has plural holes and is formed by coating an insulation material on the un-doped semiconductor layer, undergoing exposure and development the insulation material, and dry etching, so that the insulation layer functions as a selective growth mask with the holes;
performing selective growth, wherein nanowires vertically grow on the un-doped semiconductor layer through the holes of the selective growth mask;
performing lateral epitaxial growth, wherein the nanowires are grown laterally to form widened nanowires, the lateral epitaxial growth of the widened nanowires is controlled by adding additives of different concentration gradients;
performing lateral coalescence, wherein a flat bump-free coalescence film from the top of the widened nanowires is formed;
performing high temperature annealing, wherein a grain boundary at the junction of the widened nanowires is eliminated with a high temperature gas; and
performing LED structural growth, wherein a monocrystalline semiconductor structure grows from the flat bump-free coalescence film, and the monocrystalline semiconductor structure is used to manufacture light-emitting components.

2. The production method for flat substrate with low defect density of claim 1, wherein the substrate is a sapphire substrate, a silicon (Si) substrate, a silicon carbide (SiC) substrate, or a lithium aluminate substrate.

3. The production method for flat substrate with low defect density of claim 1, wherein the un-doped semiconductor layer is formed by Metal-Organic Chemical Vapor Deposition (MOCVD).

4. The production method for flat substrate with low defect density of claim 1, wherein the un-doped semiconductor layer is made of gallium nitride (GaN), aluminum nitride (AlN), indium nitride (InN), indium gallium nitride (InGaN), aluminum gallium nitride (AlGaN), or aluminum indium gallium nitride (AlInGaN).

5. The production method for flat substrate with low defect density of claim 1, wherein the insulation layer is made of silicon dioxide (SiO₂) or silicon nitride (SiNₓ).

6. The production method for flat substrate with low defect density of claim 1, wherein the insulation layer is formed by a process of Plasma Enhanced Chemical Vapor Deposition (PECVD).

7. The production method for flat substrate with low defect density of claim 1, wherein the length to width ratio of one said nanowire is 10 to 3.

8. The production method for flat substrate with low defect density of claim 1, wherein the high temperature gas is argon gas or hydrogen gas.

9. The production method for flat substrate with low defect density of claim 1, wherein the monocrystalline semiconductor structure is formed by a process of Hydride Vapour Phase Epitaxy (HVPE).
